(19) United States
(12) Patent Application Publication
(10) Pub. No.: US 2022/0050525 A1
(43) Pub. Date: Feb. 17, 2022

(54) SENSATION INDUCTION DEVICE AND SOUND OUTPUT SYSTEM

(71) Applicant: Sony Corporation, Tokyo (JP)

(72) Inventor: Yusuke MISAWA, Tokyo (JP)

(73) Assignee: Sony Corporation, Tokyo (JP)

(21) Appl. No.: 17/274,794

(22) PCT Filed: Sep. 18, 2018
(86) PCT No.: PCT/JP2018/034458

§ 371 Date: Mar. 10, 2021

(51) Int. Cl. G06F 3/01; G06F 3/16; H04R 1/10

(52) U.S. Cl. CPC G06F 3/016; H04R 1/105; G06F 3/167

(57) ABSTRACT

[Problem] To enable presentation of sound in a more suitable manner even in a situation where a sound output unit with limited performance to output a part of frequency components is applied.

[Solution] A sensation induction device including: a vibration unit that has a long shape and vibrates in the long direction; and a support unit that supports the vibration unit in the vicinity of a portion where at least a part of a predetermined portion of a user contacts in a state where the user listens to sound, wherein vibration of the vibration unit is controlled on the basis of a part of frequency components included in sound to be output such that the vibration is associated with output of sound from a predetermined sound output unit.

### FIELD

The present disclosure relates to a sensation induction device and a sound output system.

### BACKGROUND

In recent years, with development of a technology for manufacturing various devices, it has become possible to provide smaller terminal devices capable of voice communication, such as so-called mobile phones. For example, Patent Literature 1 discloses an example of a small terminal device capable of voice communication, which is a so-called mobile phone. In addition, in recent years, small terminal devices and thin terminal devices such as smartphones and tablet terminals, which are capable of not only voice communication but also listening to pieces of music, watching moving images, and the like and are configured to be portable, are also becoming popular.

### CITATION LIST

### Patent Literature

Patent Literature 1: JP 2013-232852 A

### SUMMARY

### Technical Problem

In addition, in recent years, with development of various technologies related to communication, such as encoding technologies for voice signals and sound signals, it has become possible to widen bands of sound signals transmitted and received via networks (for example, voice signals) and to improve sound quality of the sound signals. On the other hand, with downsizing of devices such as speakers that output sound (for example, voices, pieces of music, and sound effects) (hereinafter also referred to as “sound output units”), sound reproduction performance may be limited, and reproduction of sound having a wider band and higher sound quality (for example, reproduction of a low frequency component) may be difficult.

Therefore, the present disclosure proposes a technology capable of presenting sound in a more suitable manner even in a situation where a sound output unit with limited performance to output a part of frequency components is applied.

### Solution to Problem

According to the present disclosure, a sensation induction device is provided. The sensation induction device includes a vibration unit that has a long shape and vibrates in a long direction and a support unit that supports the vibration unit in a vicinity of a portion where at least a part of a predetermined portion of a user contacts in a state where the user listens to sound, wherein vibration of the vibration unit is controlled on the basis of a part of frequency components included in sound to be output such that the vibration is associated with output of sound from a predetermined sound output unit.

Moreover, according to the present disclosure, a sound output system is provided. The sound output system includes a sound output unit that outputs sound, a vibration unit that has a long shape and vibrates in a long direction and a control unit that controls vibration of the vibration unit, wherein the vibration unit is supported in a vicinity of a portion where at least a part of a predetermined portion of a user contacts in a state where the user listens to sound, and the control unit controls vibration of the vibration unit on the basis of a part of frequency components included in sound to be output such that the vibration is associated with output of sound from the sound output unit.

### Advantageous Effects of Invention

As described above, according to the present disclosure, there is provided a technology capable of presenting sound in a more suitable manner even in a situation where a sound output unit with limited performance to output a part of frequency components is applied.

Note that the effects described above are not necessarily limitative, and any of the effects described in the present specification or other effects that can be grasped from the present specification may be exhibited in addition to or in place of the effects described above.

### BRIEF DESCRIPTION OF DRAWINGS

FIG. 1 is an explanatory diagram for describing an example of a schematic configuration of a terminal device according to an embodiment of the present disclosure.

FIG. 2 is an explanatory diagram for describing an example of a sound output device according to a comparative example.

FIG. 3 is an explanatory diagram for describing an outline of an aspect of a configuration of a sound output system according to the embodiment.

FIG. 4 is an explanatory diagram for describing an outline of a mechanism in which the sound output system according to the embodiment presents sound to a user.

FIG. 5 is a block diagram illustrating an example of a functional configuration of the sound output system according to the embodiment.

FIG. 6 is an explanatory diagram for describing an example of a schematic configuration of a sound output system according to a modification.

FIG. 7 is an explanatory diagram for describing an outline of an example of a configuration of a sensation induction device according to the modification.

FIG. 8 is an explanatory diagram for describing an outline of an example of a method of disposing vibration units in the sensation induction device according to the modification.

### DESCRIPTION OF EMBODIMENTS

Hereinafter, preferred embodiments of the present disclosure will be described in detail with reference to the accompanying drawings. Note that, in the present specification and the drawings, components having substantially the same functional configuration are denoted by the same reference signs, and a duplicate description will be omitted.

Note that the description will be made in the following order.

1. Schematic Configuration

2. Technical Idea

3. Functional Configuration

4. Modification

5. Conclusion

### 1. SCHEMATIC CONFIGURATION

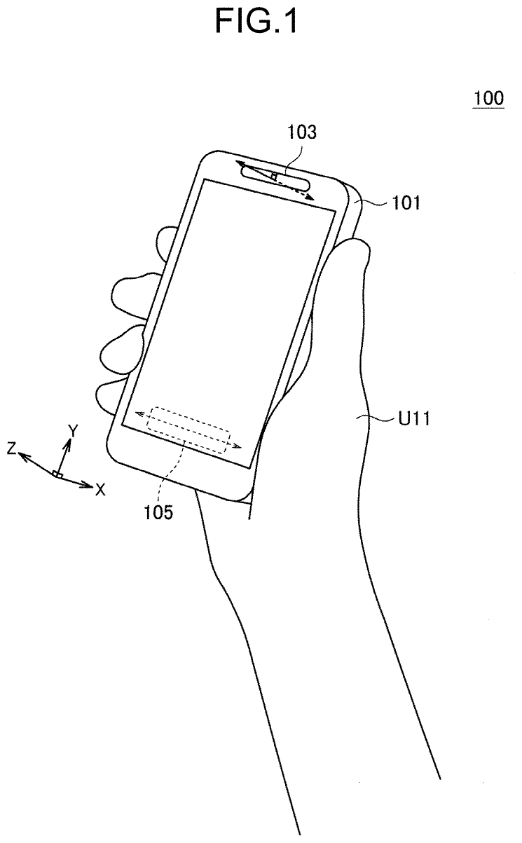

First, as an example of a configuration of a sound output system according to an embodiment of the present disclosure, an example of a case where the sound output system is configured as a terminal device configured to be portable, such as a so-called smartphone, will be described with reference to FIG. 1. FIG. 1 is an explanatory diagram for describing an example of a schematic configuration of the terminal device according to the embodiment of the present disclosure.

As illustrated in FIG. 1, a terminal device 100 according to the present embodiment includes a case 101, a sound output unit 103, and a vibration unit 105.

The case 101 supports various devices constituting the terminal device 100. As a specific example, the case 101 supports the various devices by disposing the various devices at least in a part of the case 101 (for example, by incorporating the various devices). As a specific example, the case 101 supports the sound output unit 103 and the vibration unit 105 so as to be disposed at predetermined positions. That is, the case 101 corresponds to an example of a “support unit” in the terminal device 100.

In the example illustrated in FIG. 1, the case 101 is formed in a substantially plate shape, and has a substantially rectangular shape in which a portion formed in a planar shape (for example, an upper surface or a lower surface) has the long direction and the short direction. Thus, in the following description, for convenience, the long direction and the short direction of the portion formed in a planar shape of the case 101 formed in a substantially plate shape are also referred to as “Y direction” and “X direction”, respectively, and the thickness direction of the case 101 is also referred to as “Z direction”.

In the example illustrated in FIG. 1, the terminal device 100 is held by a user by the user gripping side portions (that is, end portions in the Y direction) of the case 101 by a hand or the like.

The sound output unit 103 is configured by a sound output device such as a so-called speaker, and outputs sound (for example, voices, pieces of music, and sound effects) to present desired information to the user. In the example illustrated in FIG. 1, the sound output unit 103 is configured to reproduce desired sound by vibrating a diaphragm in the thickness direction of the case 101 (Z direction).

For example, in a state where the user holds the terminal device 100 so that the terminal device 100 is positioned in the vicinity of an ear of the user to listen to sound, the sound output unit 103 is supported by the case 101 so as to be positioned in the vicinity of the ear. As a more specific example, in the example illustrated in FIG. 1, the sound output unit 103 is supported by the case 101 so as to be positioned in the vicinity of one end portion of the case 101 in the long direction (Y direction).

Like a so-called actuator, the vibration unit 105 converts an input electric signal into physical vibration and output the vibration, so as to present the vibration to the user holding the case 101. As a specific example, the vibration unit 105 drives an actuator by an input electric signal and vibrates a vibrator, so as to convert the electric signal into physical vibration and output the vibration. In the example illustrated in FIG. 1, the vibration unit 105 is supported by the case 101 so that a vibration direction of the vibration unit 105 substantially matches the short direction out of the directions along the portion formed in a planar shape having a substantially rectangular shape of the case 101 formed in a substantially plate shape. In other words, the vibration unit 105 is supported by the case 101 so that the vibration direction of the vibration unit 105 is substantially perpendicular to the long direction of the portion formed in a planar shape having a substantially rectangular shape of the case 101. With this configuration, in a state where the side portions of the case 101 (that is, the end portions in the Y direction) are gripped by a hand of the user, vibration is presented to the hand of the user by the vibration unit 105.

For example, the vibration unit 105 having a long shape and configured to vibrate in the long direction is preferably applied. As a more specific example, a linear vibration actuator (linear resonant actuator (LRA)) may be applied as the vibration unit 105. With such a configuration, even in a situation where an installation space for the vibration unit 105 is limited, it is possible to secure larger vibration amplitude in the short direction (Y direction) of the portion formed in a planar shape of the case 101 formed in a substantially plate shape, and obtain higher vibration intensity in the short direction.

In addition, the vibration unit 105 and the sound output unit 103 are preferably supported by the case 101 so that the vibration direction of the vibration unit 105 and a vibration direction of the diaphragm of the sound output unit 103 are substantially perpendicular to each other, or are twisted from each other. As a more specific example, in the example illustrated in FIG. 1, the vibration direction of the diaphragm of the sound output unit 103 substantially matches the thickness direction of the case 101 (that is, Z direction), and the vibration direction of the vibration unit 105 substantially matches the short direction of the portion formed in a planar shape having a substantially rectangular shape of the case 101 (that is, Y direction). That is, the vibration unit 105 is supported so that the vibration direction of the vibration unit 105 and the long direction of the case 101 are substantially perpendicular to each other. In other words, the vibration unit 105 is supported so that the vibration direction of the vibration unit 105 and the thickness direction of the case 101, in which the diaphragm of the sound output unit 103 vibrates, are substantially perpendicular to each other. With such a configuration, it is possible to further reduce influence of interference of vibration of one of the vibration unit 105 and the sound output unit 103 with vibration of the other.

In addition, the vibration unit 105 is preferably supported by the case 101 so as to be positioned in the vicinity of a portion gripped by a hand of a user in a state where the user uses the terminal device 100 (for example, a state where the user listens to sound output from the sound output unit 103). As a specific example, in the example illustrated in FIG. 1, the vibration unit 105 is supported by the case 101 so as to be positioned in the vicinity of one of end portions of the case 101 in the long direction on the opposite side of the end portion where the sound output unit 103 is supported in the vicinity. In addition, since the vibration unit 105 and the sound output unit 103 are supported by the case 101 so as to be separated from each other, it is possible to further reduce influence of interference of vibration of one of the vibration unit 105 and the sound output unit 103 with vibration of the other. In addition, in the example illustrated in FIG. 1, in view of a characteristic of presenting vibration to a hand of the user gripping the case 101, it is desirable that the vibration direction of the vibration unit 105 is set so that vibration is more easily transmitted to the hand. Thus, in the example illustrated in FIG. 1, as described above, the vibration unit 105 is supported by the case 101 so that the vibration direction of the vibration unit 105 substantially matches the short direction out of the directions along the portion formed in a planar shape having a substantially rectangular shape of the case 101 formed in a substantially plate shape.

As the example of the configuration of the sound output system according to the embodiment of the present disclosure, the example of the case where the sound output system is configured as a terminal device configured to be portable, such as a so-called smartphone, has been described above with reference to FIG. 1.

### 2. TECHNICAL IDEA

Subsequently, a basic technical idea of the sound output system according to the embodiment of the present disclosure will be described.

A device configured to be portable, such as the terminal device 100 described with reference to FIG. 1, tends to be particularly small and thin in recent years, and accordingly, a space for disposing various devices (for example, a space in the case for incorporating the various devices) is limited. In view of such tendency, for example, a smaller sound output device for implementing sound output, such as the sound output unit 103 illustrated in FIG. 1, tends to be adopted.

In addition, in recent years, with development of various technologies related to communication, such as encoding technologies for voice signals and sound signals, it has become possible to widen bands of sound signals transmitted and received via networks (for example, voice signals) and to improve sound quality of the sound signals.

On the other hand, the small sound output device as described above may have limited sound reproduction performance, and may have difficulty in reproducing sound having a wider band and higher sound quality. As a specific example, the vibration width of the diaphragm may be limited in a case where sound is reproduced by vibrating the diaphragm in the thickness direction of the thin case 101, as in the sound output unit 103 illustrated in FIG. 1. In such a situation, it may be difficult to reproduce, particularly, a low frequency component of sound to be output.

In view of such a situation, in the present disclosure, there is proposed a technology capable of presenting sound in a more suitable manner even in a situation where a sound output unit with limited performance to output sound (for example, a sound output unit with limited performance to output a part of frequency components such as low frequency components) is applied. Specifically, in the sound output system according to the embodiment of the present disclosure, by presenting vibration to a user by the vibration unit, a frequency component that is difficult to reproduce by the sound output unit (for example, a low frequency component) is supplemented by a haptic effect. That is, in the sound output system according to the present embodiment, for example, sound having a wider band and higher sound quality is reproduced in a more suitable manner by combining output of sound from the sound output unit and presentation of vibration by the vibration unit.

### Comparative Example: One Example of Device Presenting Sound by Bone Conduction

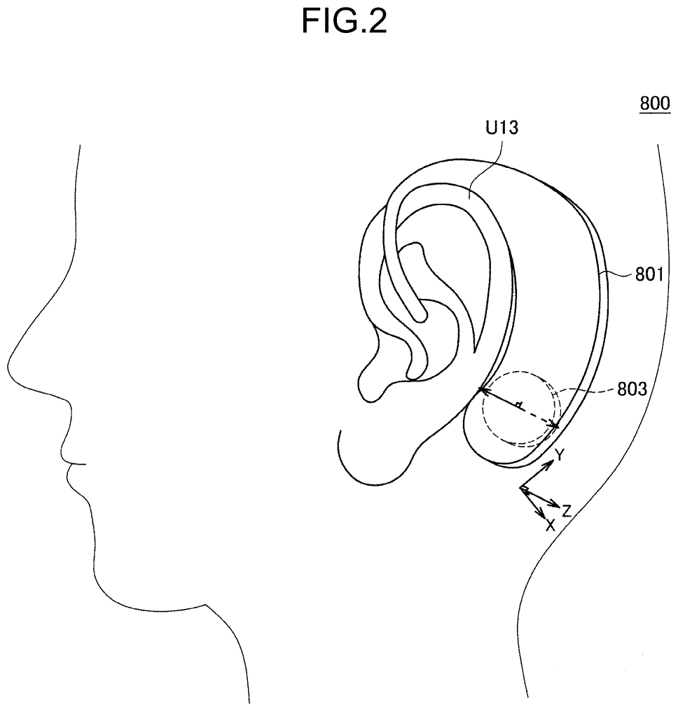

Here, as a comparative example, an example of a technology that allows a user to perceive sound by presentation of vibration (in other words, technology that presents sound to the user in an audible manner by presentation of vibration) will be described with reference to FIG. 2. FIG. 2 is an explanatory diagram for describing an example of a sound output device according to the comparative example, and illustrates an example of a device that presents sound to a user by so-called bone conduction.

A sound output device 800 according to the comparative example illustrated in FIG. 2 schematically indicates a so-called bone conduction type sound output device (for example, a device such as an earphone, a headphone, or a hearing aid). As illustrated in FIG. 2, the sound output device 800 includes a case 801 and a vibration unit 803.

The case 801 is configured to be attached to the head of a user so that at least a part of the case 801 contacts a part of the head (for example, a temporal region). For example, in the example illustrated in FIG. 2, the case 801 is attached to an ear U13 of the user so as to be held in such a way that a part of the case 801 positioned on the rear side of the ear U13 contacts a part of the temporal region of the user.

In addition, the case 801 supports the vibration unit 803 so that the vibration unit 803 is positioned in the vicinity of a portion that contacts a part of the head when the case 801 is attached to the head of the user. Note that, in the following description, for convenience, in a portion where the case 801 contacts a part of the head of the user (that is, portion where the vibration unit 803 is held in the vicinity), a direction perpendicular to the part of the head is also referred to as “Z direction”, and two directions perpendicular to the Z direction and perpendicular to each other are also referred to as “X direction” and “Y direction”.

Like a so-called actuator, the vibration unit 803 converts an input electric signal into physical vibration and output the vibration, so as to present the vibration to the user holding the case 801. In addition, in a portion where the case 801 contacts a part of the head, the vibration unit 803 is supported by the case 801 so that a vibration direction is substantially perpendicular to the part of the head (that is, so as to vibrate in the Z direction).

With the above configuration, by control of vibration of the vibration unit 803 on the basis of an electric signal corresponding to sound to be output, the vibration of the vibration unit 803 propagates through at least a part of the body of the user (for example, the skull and the like) and is transmitted to an auditory nerve, so that the sound is perceived by the user.

(One Aspect of Configuration)

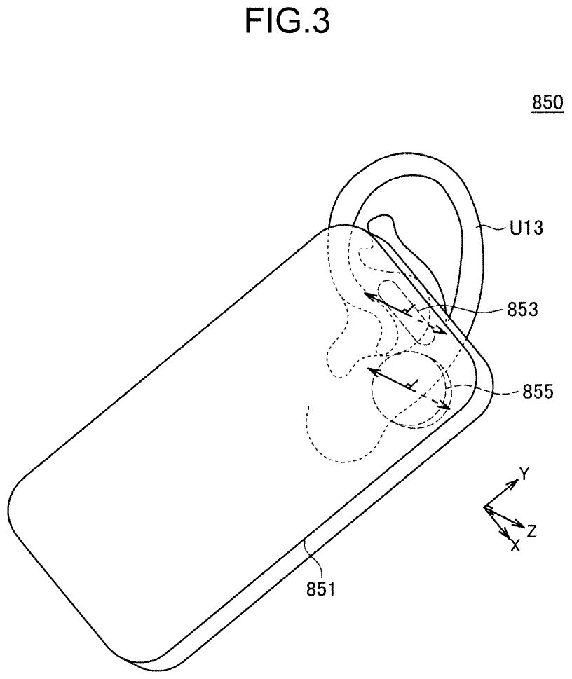

Here, an aspect of the configuration of the sound output system according to the embodiment of the present disclosure will be described with reference to FIG. 3. FIG. 3 is an explanatory diagram for describing an outline of the aspect of the configuration of the sound output system according to the present embodiment, and illustrates, similarly to the example illustrated in FIG. 1, an example of a case where the sound output system is configured as a terminal device configured to be portable, such as a so-called smartphone. Note that, in the following description, for convenience, the terminal device illustrated in FIG. 3 may be referred to as “terminal device 850” in order to distinguish it from the terminal device 100 illustrated in FIG. 1. In addition,

The terminal device 850 illustrated in FIG. 3 includes a case 851, a sound output unit 853, and a vibration unit 855. Note that the case 851 and the sound output unit 853 correspond to the case 101 and the sound output unit 103 in the terminal device 100 illustrated in FIG. 1. Thus, detailed description of the case 851 and the sound output unit 853 is omitted. In addition, in the following description, for convenience, the long direction and the short direction of a portion formed in a planar shape of the case 851 formed in a substantially plate shape are also referred to as “Y direction” and “X direction”, respectively, and the thickness direction of the case 851 is also referred to as “Z direction”, similarly to the example illustrated in FIG. 1. That is, in a state where the user holds the terminal device 850 so that the terminal device 850 is positioned in the vicinity of the ear U13 of the user to listen to sound, the thickness direction of the case 851 (Z direction) substantially matches a direction perpendicular to a portion of the head (for example, a temporal region) of the user where the terminal device 850 is held in the vicinity.

Like a so-called actuator, the vibration unit 855 converts an input electric signal into physical vibration and output the vibration, so as to present the vibration to the user holding the case 851.

The vibration unit 855 is supported by the case 851 so as to be positioned in the vicinity of a part of the case 851 contacting a part of the head of the user in a state where the user holds the terminal device 850 so that the terminal device 850 is positioned in the vicinity of the ear U13 of the user to listen to sound. At this time, the vibration unit 855 is supported by the case 851 so that a vibration direction is substantially perpendicular to the portion of the head of the user where the part of the case 851 contacts.

With the above configuration, vibration of the vibration unit 855 is controlled in association with output of sound from the sound output unit 853, on the basis of an electric signal corresponding to the sound. That is, vibration from the vibration unit 855 is presented to the user in association with output of sound from the sound output unit 853. With such a configuration, the terminal device 850 can be expected to have an effect of supplementing a frequency component that is difficult to reproduce sound by the sound output unit 853 with vibration of the vibration unit 855, even in a situation where a sound output device with limited sound reproduction performance is applied as the sound output unit 853.

On the other hand, in the terminal device 850 illustrated in FIG. 3, the intensity of output vibration may be limited since vibration amplitude of the vibration unit 855 is limited in view of a characteristic of vibrating the vibration unit 855 in the thickness direction. In view of such a situation, in the present disclosure, there is proposed the terminal device 100 described with reference to FIG. 1 as an example of a configuration capable of presenting vibration with higher intensity on the basis of a technical idea similar to that of the terminal device 850 illustrated in FIG. 3.

(Mechanism for Supplementing Sound Reproduction by Presentation of Vibration)

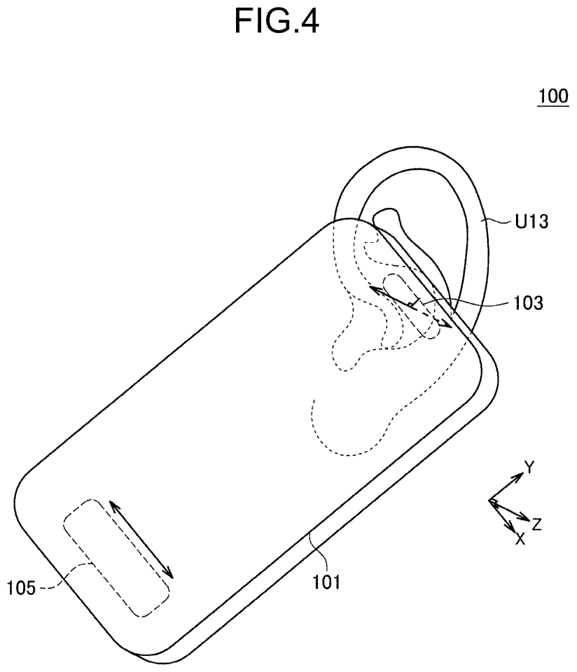

Subsequently, description will be made of a mechanism for supplementing a frequency component that is difficult to reproduce sound by the sound output unit 103 by presentation of vibration to a user by the vibration unit 105 in the terminal device 100 described with reference to FIG. 1. For example, FIG. 4 is an explanatory diagram for describing an outline of the mechanism in which the sound output system according to the embodiment of the present disclosure presents sound to the user.

In the terminal device 850 illustrated in FIG. 3, the vibration unit 855 is held so as to be positioned in the vicinity of a temporal region of the user, and the vibration unit 855 vibrates in a direction perpendicular to a portion of the temporal region where a part of the case 851 contacts (Z direction), so that the vibration is presented to the user.

In contrast, in the terminal device 100, as illustrated in FIG. 4, the vibration unit 105 is supported by the case 101 so as to be positioned in the vicinity of one of the end portions of the case 101 in the long direction (Y direction) on the opposite side of the end portion where the sound output unit 103 is held in the vicinity. In addition, at this time, the vibration unit 105 is supported by the case 101 so as to vibrate in the short direction of the case 101 (Y direction). Thus, in the terminal device 100, for example, vibration by the vibration unit 105 is presented to a hand of a user gripping the case 101 or a part of the head of the user (for example, a cheek) that contacts a portion of the case 101 where the vibration unit 105 is supported in the vicinity.

With such a configuration, the terminal device 100 associates output of sound by the sound output unit 103 and presentation of vibration by the vibration unit 105 to present sound having a wider band and higher sound quality to the user. As a specific example, by supplementation of a frequency component that is difficult to reproduce by the sound output unit 103 by presentation of vibration by the vibration unit 105, sound can be presented to the user in a more suitable manner even in a case where sound reproduction performance of the sound output unit 103 is limited. Note that, in this case, for example, it is only required to drive the vibration unit 105 on the basis of an electric signal corresponding to the frequency component that is difficult to reproduce by the sound output unit 103 among frequency components of sound to be presented.

Note that, as described above, the vibration unit 105 having a long shape and configured to vibrate in the long direction is applied in the terminal device 100, and the vibration unit 105 is supported so that the long direction (that is, vibration direction) substantially matches the short direction of the case 101 (Y direction). Thus, the terminal device 100 can secure larger vibration amplitude of the vibration unit 105 than in a case where the vibration unit 855 is vibrated in the thickness direction of the case 851 (Z direction) as in the terminal device 850 illustrated in FIG. 3. With this configuration, the terminal device 100 can obtain higher vibration intensity than the terminal device 850.

In a situation where sound is perceived by presentation of vibration, it tends to be desirable to present vibration with higher intensity in a case where a low frequency component of the sound is reproduced, than in a case where a high frequency component is reproduced. In addition, as the volume of sound to be presented increases, the intensity of vibration required to reproduce the sound tends to increase. From such a background, the terminal device 100 can reproduce a low frequency component of sound to be presented with higher reproducibility than that of the terminal device 850.

As a more specific example of the control, in a case where a low frequency component of sound to be presented is supplemented by presentation of vibration by the vibration unit 105, for example, the vibration of the vibration unit 105 is preferably controlled on the basis of a fundamental wave among frequency components constituting the sound (in other words, a group of sine waves). Needless to say, the control of vibration of the vibration unit 105 is only required to include at least the fundamental wave, and may include, for example, some harmonics (particularly, harmonics on the low frequency side) among frequency components constituting sound to be presented, in addition to the fundamental wave.

In addition, as illustrated in FIGS. 1 and 4, the vibration unit 105 and the sound output unit 103 is supported by the case 101 so that the vibration direction of the vibration unit 105 (that is, Y direction) and the vibration direction of the diaphragm of the sound output unit 103 (that is, Z direction) are substantially perpendicular to each other, or are twisted from each other. Thus, the terminal device 100 has a feature that vibration of the vibration unit 105 and vibration of the diaphragm of the sound output unit 103 are less likely to interfere with each other, and influence of the interference is less likely to be actualized.

Note that, in the examples illustrated in FIGS. 1 and 4, the terminal device 100 corresponds to an example of a “sensation induction device” that presents vibration to a user in association with output of sound. In addition, a state where the user listens to sound output from the sound output unit 103 while holding the terminal device 100 by the hand of the user or the like corresponds to an example of a “use state” of the terminal device 100. As a more specific example, a state where the user listens to sound output from the sound output unit 103 while holding the terminal device 100 so that the terminal device 100 is positioned in the vicinity of the ear of the user corresponds to an example of the “use state” of the terminal device 100. In addition, a state where the user listens to sound output from the sound output unit 103 while gripping the terminal device 100 by the hand of the user and keeping the terminal device 100 away from the ear of the user also corresponds to an example of the “use state” of the terminal device 100. In addition, in the example illustrated in FIG. 3, the terminal device 850 corresponds to an example of the “sensation induction device” described above. In this case, a state where the user listens to sound output from the sound output unit 853 while holding the terminal device 850 so that the terminal device 850 is positioned in the vicinity of the ear of the user corresponds to an example of the “use state” of the terminal device 100. In other words, in the sound output system according to the embodiment of the present disclosure, a state where a user listens to sound output from the sound output unit and vibration can be presented to a part of the user (for example, a hand) by the vibration unit corresponds to an example of the “use state”.

The basic technical idea of the sound output system according to the embodiment of the present disclosure has been described above with reference to FIGS. 2 to 4.

### 3. FUNCTIONAL CONFIGURATION

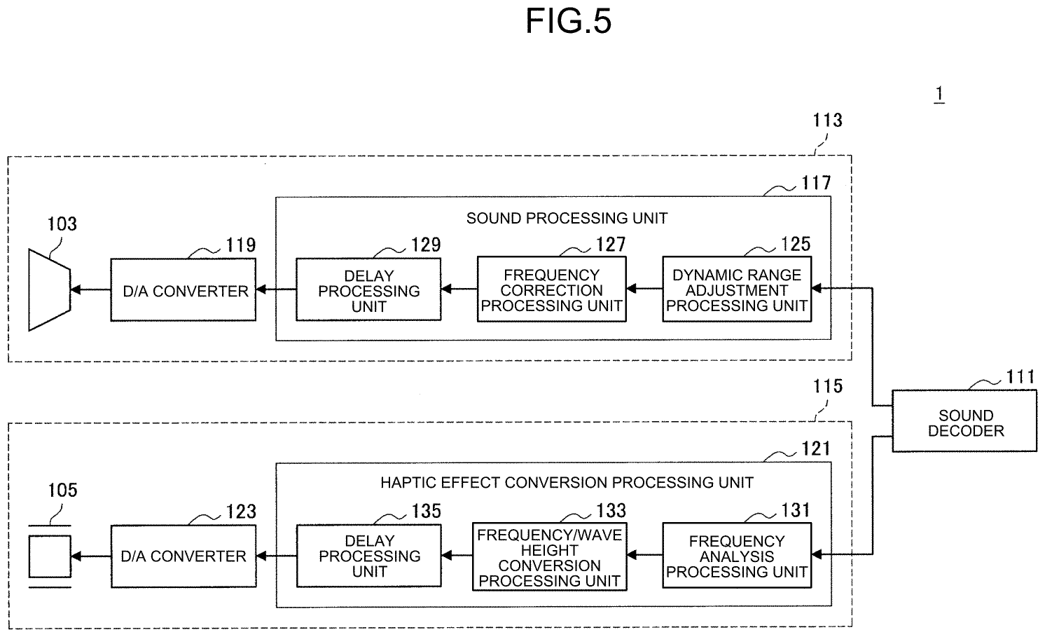

Subsequently, an example of a functional configuration of the sound output system according to the embodiment of the present disclosure will be described. For example, FIG. 5 is a block diagram illustrating the example of the functional configuration of the sound output system according to the embodiment of the present disclosure.

As illustrated in FIG. 5, a sound output system 1 according to the present embodiment includes a sound decoder 111, a sound processing unit 117, a D/A converter 119, the sound output unit 103, a haptic effect conversion processing unit 121, a D/A converter 123, and the vibration unit 105. Note that the sound output unit 103 and the vibration unit 105 are substantially similar to the sound output unit 103 and the vibration unit 105 in the terminal device 100 illustrated in FIGS. 1 and 4, and thus detailed description thereof will be omitted.

The sound decoder 111 generates a digital sound signal (in other words, drive signal) for driving the sound output unit 103 in order to output sound to be output via the sound output unit 103. As a specific example, in a situation where a received voice is output in voice communication, the sound decoder 111 restores a received voice packet signal received from the opposite side and converts the received voice packet signal into a digital sound signal (for example, PCM signal) for driving the sound output unit 103. Then, the sound decoder 111 outputs the generated sound signal to each of the sound processing unit 117 and the haptic effect conversion processing unit 121.

The sound processing unit 117 is a configuration for performing various types of signal processing on the input sound signal. For example, the sound processing unit 117 includes a dynamic range adjustment processing unit 125, a frequency correction processing unit 127, and a delay processing unit 129.

The dynamic range adjustment processing unit 125 corrects a dynamic range of the input sound signal. As a specific example, the dynamic range adjustment processing unit 125 may correct a dynamic range of the input sound signal in accordance with setting related to output of sound via the sound output unit 103.

The frequency correction processing unit 127 performs frequency correction processing on the input sound signal. As a specific example, the frequency correction processing unit 127 may apply a predetermined filter to the input sound signal to remove a noise component included in the sound signal. In addition, the frequency correction processing unit 127 may perform various types of correction processing on the input sound signal to adjust reverberation time of sound output via the sound output unit 103.

The delay processing unit 129 performs delay processing on the input sound signal to control timing at which the sound output unit 103 positioned in the subsequent stage is driven on the basis of the sound signal (that is, timing at which sound corresponding to the sound signal is output). By the delay processing unit 129 performing the delay processing on the input sound signal, for example, it is possible to synchronize, on the basis of the sound signal generated by the sound decoder 111, timing at which sound is output from the sound output unit 103 and timing at which vibration is presented by the vibration unit 105 to be described later.

Note that the configuration of the sound processing unit 117 described above is merely an example, and the configuration of the sound processing unit 117 is not necessarily limited by the example. That is, the configuration of the sound processing unit 117 may be appropriately changed in accordance with processing applied to the sound signal output from the sound decoder 111.

The D/A converter 119 digital-analog converts the digital sound signal output from the sound processing unit 117 into an analog sound signal, and supplies the analog sound signal obtained by the conversion to the sound output unit 103. As a result, the sound output unit 103 is driven, and the sound output unit 103 outputs sound corresponding to the sound signal.

The haptic effect conversion processing unit 121 is a configuration for converting the input sound signal into a drive signal for driving the vibration unit 105. That is, the haptic effect conversion processing unit 121 can correspond to an example of a “control unit” that controls vibration of the vibration unit 105. In addition, a control unit that controls operation of the haptic effect conversion processing unit 121 may be separately provided. In this case, the control unit can correspond to an example of the “control unit” that controls vibration of the vibration unit 105. For example, the haptic effect conversion processing unit 121 includes a frequency analysis processing unit 131, a frequency/wave height conversion processing unit 133, and a delay processing unit 135.

The frequency analysis processing unit 131 performs frequency analysis processing on the input sound signal to extract frequency components included in the sound signal (for example, a group of sine waves including a fundamental wave and various harmonics). Then, the frequency analysis processing unit 131 outputs a result of the frequency analysis processing on the sound signal (for example, a result of extracting each frequency component) to the frequency/wave height conversion processing unit 133 positioned in the subsequent stage.

The frequency/wave height conversion processing unit 133 converts, on the basis of the result of the frequency analysis processing on the sound signal output from the sound decoder 111, at least a part of the frequency components included in the sound signal into a drive signal for driving the vibration unit 105.

As a specific example, the frequency/wave height conversion processing unit 133 may extract a frequency component used for presentation of vibration by the vibration unit 105 among the frequency components included in the input sound signal. As a more specific example, in a case where a low frequency component of the sound signal output from the sound decoder 111 is presented to a user by vibration of the vibration unit 105, the frequency/wave height conversion processing unit 133 may extract a part of frequency components including at least a fundamental wave among the frequency components constituting the sound signal (a group of sine waves).

In addition, the frequency/wave height conversion processing unit 133 may control, in accordance with the intensity of vibration presented by the vibration unit 105, the wave height (amplitude) of the frequency component of the sound signal used to drive the vibration unit 105.

In addition, the frequency/wave height conversion processing unit 133 may perform various types of correction processing on the frequency component of the sound signal used to drive the vibration unit 105 to adjust reverberation time of vibration presented by the vibration unit 105.

Note that the frequency/wave height conversion processing unit 133 described above is merely an example, and at least a part of the processing content may be appropriately changed in accordance with the control content of driving of the vibration unit 105 based on the input sound signal. As a specific example, setting of a frequency component extracted from the sound signal output from the sound decoder 111 may be changed in accordance with performance (for example, sound reproduction performance) of a sound output device applied as the sound output unit 103.

As described above, the frequency/wave height conversion processing unit 133 converts the input digital sound signal into a digital drive signal for driving the vibration unit 105, and outputs the digital drive signal to the delay processing unit 135 positioned in the subsequent stage.

The delay processing unit 135 performs delay processing on the input drive signal to control timing at which the vibration unit 105 positioned in the subsequent stage is driven on the basis of the drive signal (that is, timing at which vibration corresponding to the drive signal is presented). By the delay processing unit 135 performing the delay processing on the input drive signal, for example, it is possible to synchronize, on the basis of the sound signal generated by the sound decoder 111, timing at which sound is output from the sound output unit 103 and timing at which vibration is presented by the vibration unit 105 to be described later.

The D/A converter 123 digital-analog converts the digital drive signal output from the haptic effect conversion processing unit 121 into an analog drive signal, and supplies the analog drive signal obtained by the conversion to the vibration unit 105. As a result, the vibration unit 105 is driven, and vibration in accordance with the drive signal is presented.

Note that there is no particular limitation on a method of synchronizing, on the basis of the sound signal generated by the sound decoder 111, timing at which sound is output from the sound output unit 103 and timing at which vibration is presented by the vibration unit 105.

As a specific example, a predetermined delay amount may be applied to each of the delay processing units 129 and 135 in accordance with a characteristic (particularly, characteristic related to delay) of each device constituting a portion related to sound output denoted by a reference numeral 113, and a characteristic of each device constituting a portion related to presentation of vibration denoted by a reference numeral 115.

In addition, as another example, by a predetermined control unit controlling the delay amount applied to each of the delay processing units 129 and 135, timing at which sound is output from the sound output unit 103 and timing at which vibration is presented by the vibration unit 105 may be synchronized.

In addition, as another example, by the delay processing units 129 and 135 operating in association with each other, timing at which sound is output from the sound output unit 103 and timing at which vibration is presented by the vibration unit 105 may be synchronized.

In addition, locations where each of the configuration related to output of sound denoted by the reference numeral 113 (hereinafter also referred to as a “first output unit 113”), the configuration related to presentation of vibration (that is, tactile presentation) denoted by the reference numeral 115 (hereinafter also referred to as a “second output unit 115”), and the sound decoder 111 are provided are not particularly limited. As a specific example, the first output unit 113, the second output unit 115, and the sound decoder 111 may be integrally configured. Note that the terminal device 100 described with reference to FIGS. 1 and 4 can be implemented by integrally configuring each configuration of the sound output system 1 illustrated in FIG. 5 so as to be disposed in the case 101 (for example, so as to be incorporated into the case 101).

In addition, as another example, at least a part of the configurations of the first output unit 113, the second output unit 115, and the sound decoder 111 may be provided in another device different from a device in which another part of the configurations are provided. In addition, as another example, the first output unit 113, the second output unit 115, and the sound decoder 111 may be provided in different devices.

As a more specific example, the first output unit 113 and the second output unit 115 may be provided in different devices. In this case, the sound decoder 111 may be provided in either the device provided with the first output unit 113 or the device provided with the second output unit 115, or may be provided in another device different from these devices. Note that an example of the case where the first output unit 113 and the second output unit 115 are provided in different devices will be separately described later in detail as a modification.

Note that, among the series of devices constituting the sound output system 1, the device provided with the second output unit 115 (that is, device related to presentation of vibration via the vibration unit 105) corresponds to an example of the “sensation induction device” that presents vibration to a user.

The example of the functional configuration of the sound output system according to the embodiment of the present disclosure has been described above with reference to FIG. 5.

### 4. MODIFICATION

Subsequently, as a modification of the sound output system according to the embodiment of the present disclosure, description will be made of an example of a case where a configuration related to output of sound and a configuration related to presentation of vibration are provided in different devices.

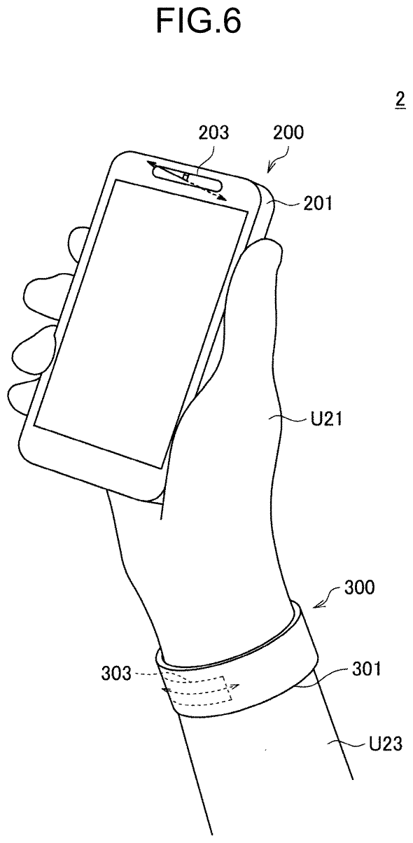

For example, FIG. 6 is an explanatory diagram for describing an example of a schematic configuration of a sound output system according to a modification. Note that, in the following description, for convenience, the sound output system according to the modification may be referred to as a “sound output system 2” in order to distinguish it from the sound output system 1 according to the embodiment described above.

As illustrated in FIG. 6, the sound output system 2 includes a terminal device 200 and a sensation induction device 300.

(Terminal Device 200)

First, the terminal device 200 will be described. The terminal device 200 is configured as, for example, a terminal device configured to be portable, such as a smartphone. The terminal device 200 has a function of outputting sound and serves as the first output unit 113 illustrated in FIG. 5.

Specifically, the terminal device 200 includes a case 201 and a sound output unit 203. Note that the sound output unit 203 is substantially similar to the sound output unit 103 in the terminal device 100 described with reference to FIG. 1, and thus detailed description thereof will be omitted.

The case 201 corresponds to the case 101 in the terminal device 100 illustrated in FIG. 1, and supports various devices constituting the terminal device 200 by disposing the various devices at least in a part of the case 201 (for example, by incorporating the various devices). As a specific example, the case 201 supports the sound output unit 203 so as to be disposed at a predetermined position. Note that the position at which the sound output unit 203 is supported by the case 201 is substantially similar to the position at which the sound output unit 103 is supported by the case 101 in the terminal device 100 illustrated in FIG. 1. In addition, the case 201 is formed in a substantially plate shape, and has a substantially rectangular shape in which a portion formed in a planar shape has the long direction and the short direction. In addition, the case 201 supports the sound output unit 203 so that the sound output unit 203 reproduces desired sound by vibrating a diaphragm in the thickness direction of the case 201.

With the above configuration, for example, in a case where a user holds the terminal device 200 so that the terminal device 200 is positioned in the vicinity of an ear of the user to listen to sound, the terminal device 200 is used by being gripped by a hand U21 of the user. In addition, at this time, the sound output unit 203 is held so as to be positioned in the vicinity of the ear of the user.

(Sensation Induction Device 300)

Subsequently, the sensation induction device 300 will be described. The sensation induction device 300 is configured as a so-called wearable terminal, and is used by being attached to an arm U23 of a user. The sensation induction device 300 has a function of presenting vibration to the user wearing the sensation induction device 300, and serves as the second output unit 115 illustrated in FIG. 5.

Specifically, the sensation induction device 300 includes a case 301 and a vibration unit 303. The vibration unit 303 corresponds to the vibration unit 105 in the terminal device 100 described with reference to FIG. 1. For example, the vibration unit 303 having a long shape and configured to vibrate in the long direction is preferably applied, similarly to the vibration unit 105 described above. As a more specific example, a linear vibration actuator can be applied as the vibration unit 303.

The case 301 includes a belt-shaped member in at least a part thereof, and the belt-shaped member is wound around the arm U23 of the user to be attached to a part of the arm U23.

The case 301 supports various devices constituting the sensation induction device 300 by disposing the various devices at least in a part of the case 301 (for example, by incorporating the various devices). Specifically, in a case where the sensation induction device 300 is attached to the arm U23 of the user, the case 301 supports the vibration unit 303 so that the vibration unit 303 is positioned in the vicinity of a portion that contacts a part of the arm U23. In addition, at this time, the case 301 supports the vibration unit 303 so that a vibration direction of the vibration unit 303 substantially matches a circumferential direction of the arm U23 to which the case 301 is attached (that is, direction along the side surface of the arm U23, in which the belt-shaped member extends). That is, in the sound output system 2 according to the modification, the case 301 corresponds to an example of the “support unit”.

With the above configuration, the sensation induction device 300 presents vibration to a user by driving the vibration unit 303 in association with the operation of the terminal device 200 outputting sound from the sound output unit 203. Note that, as long as the terminal device 200 and the sensation induction device 300 can operate in association with each other, the configuration and the control content therefor are not particularly limited. As a specific example, one of the terminal device 200 and the sensation induction device 300 may operate under control of the other. In addition, as another example, the terminal device 200 and the sensation induction device 300 may operate in association with each other by exchanging information with each other.

### Example Configuration of Sensation Induction Device 300

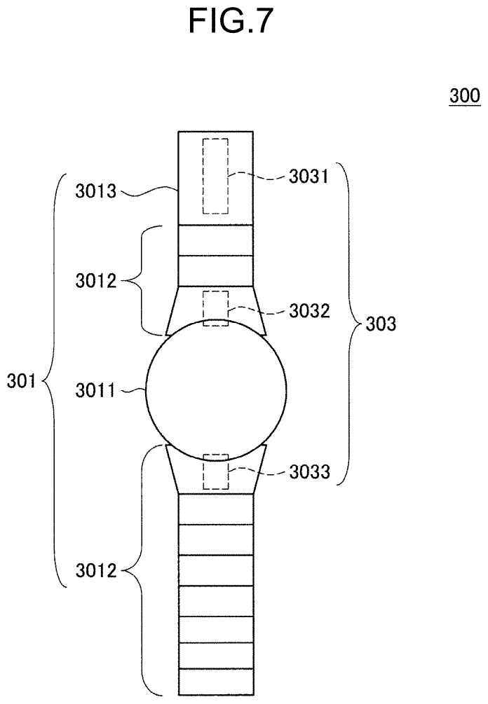

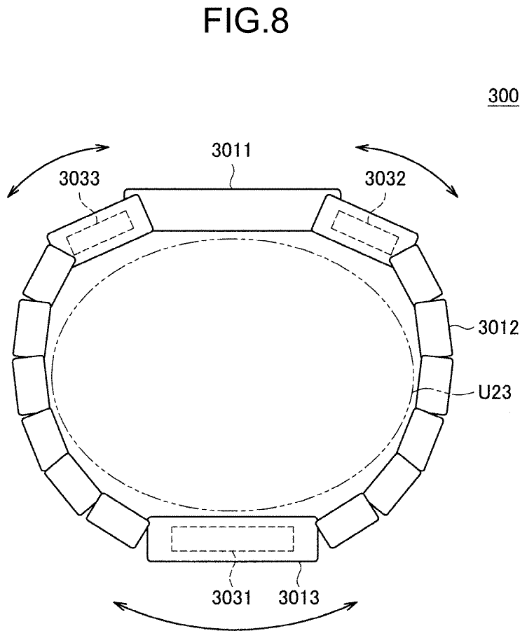

Subsequently, with reference to FIGS. 7 and 8, as an example of a more specific configuration of the sensation induction device 300 illustrated in FIG. 6, a case where the sensation induction device 300 is configured as a wristwatch-type wearable device will be described with particular attention to a method of disposing the vibration unit 303.

For example, FIG. 7 is an explanatory diagram for describing an outline of the example of the configuration of the sensation induction device 300 according to the modification, and illustrates an example of the case where the sensation induction device 300 is configured as a wristwatch-type wearable device.

In the example illustrated in FIG. 7, the sensation induction device 300 includes a bezel portion 3011, belt portions 3012, a buckle portion 3013, and vibration units 3031 to 3033. Among the components of the sensation induction device 300 illustrated in FIG. 7, the bezel portion 3011, the belt portions 3012, and the buckle portion 3013 correspond to the case 301 illustrated in FIG. 6. Thus, in the following description, the bezel portion 3011, the belt portions 3012, and the buckle portion 3013 may be simply referred to as the “case 301” when they are not particularly distinguished. In addition, the vibration units 3031 to 3033 correspond to the vibration unit 303 illustrated in FIG. 6. Thus, in the following description, the vibration units 3031 to 3033 may be simply referred to as the “vibration unit 303” when they are not particularly distinguished.

The bezel portion 3011 is a portion corresponding to a bezel of a wristwatch, for example. The bezel portion 3011 may incorporate, for example, a chip or the like for implementing various types of arithmetic processing. In addition, the bezel portion 3011 may be provided with an output interface such as a display for presenting information to a user. In addition, the bezel portion 3011 may be provided with an input interface such as a touch panel and buttons for receiving input from the user.

The belt portions 3012 and the buckle portion 3013 are, for example, portions corresponding to belts and a buckle of a wristwatch, and correspond to members for attaching the sensation induction device 300 to the arm U23 of the user. That is, a state where the belt portions 3012 are wound around the arm U23 of the user is fixed by the buckle portion 3013, so that the sensation induction device 300 is attached to the arm U23. Note that, as for the specific structures of the belt portions 3012 and the buckle portion 3013 for attaching the sensation induction device 300 to the arm U23 of the user, since structures substantially similar to those of a so-called wristwatch (that is, existing structures) can be applied, detailed description thereof will be omitted.

The vibration unit 3031 is supported by the buckle portion 3013 so that a vibration direction (long direction) substantially matches a direction in which the belt portions 3012 extend. In addition, the vibration units 3032 and 3033 are supported by the belt portions 3012 so that vibration directions (long directions) substantially match the direction in which the belt portions 3012 extend. With such a configuration, each of the vibration units 3031 to 3033 is driven in a state where the sensation induction device 300 is attached to the arm U23 of the user, so that vibration is presented to the arm U23 by the vibration units 3031 to 3033.

For example, FIG. 8 is an explanatory diagram for describing an outline of an example of the method of disposing the vibration unit 303 in the sensation induction device 300 according to the modification. Specifically, FIG. 8 schematically illustrates a situation where, in a case where the sensation induction device 300 is attached to the arm U23 of the user, vibration is presented to the arm U23 by the vibration unit 303.

As illustrated in FIG. 8, when the sensation induction device 300 is attached to the arm U23 of the user, the vibration units 3031 to 3033 are held along the circumferential direction of the arm U23. When each of the vibration units 3031 to 3033 is driven in such a state, vibration along the circumferential direction of the arm U23 is presented to the arm U23 by the vibration units 3031 to 3033. Note that, from such characteristics, the vibration direction and vibration timing of each of the vibration units 3031 to 3033 are preferably controlled so that vibration of one of the vibration units 3031 to 3033 does not cancel vibration of the rest of the vibration unit 303.

As described above, by vibrating the vibration unit 303 along the circumferential direction of the arm U23, the sensation induction device 300 can secure larger vibration amplitude of the vibration unit 303 and obtain higher vibration intensity.

With the configuration as described above, the sound output system 2 according to the modification can supplement, for example, a frequency component difficult to reproduce by the sound output unit 203 of the terminal device 200 by presentation of vibration by the vibration unit 303 of the sensation induction device 300. With such a configuration, even in a case where sound reproduction performance of the sound output unit 203 of the terminal device 200 is limited, sound can be presented to a user in a more suitable manner. Note that, in the sound output system 2 according to the modification, the sensation induction device 300 corresponds to an example of the “sensation induction device” that presents vibration to a user in association with output of sound. In addition, in the sound output system 2 according to the modification, a state where a user wears the sensation induction device 300 and the user listens to sound output from the sound output unit 203 of the terminal device 200 corresponds to an example of the “use state”.

Note that the configuration described above is merely an example, and the sound output system 2 according to the modification is not limited by the example. That is, the configuration of the sound output system 2 is not limited to the examples illustrated in FIGS. 7 and 8 as long as it is possible to associate each device so that sound output from a device corresponding to the terminal device 200 is supplemented by presentation of vibration from a device corresponding to the sensation induction device 300. In addition, in the example illustrated in FIG. 6, in view of a characteristic of presenting vibration to the arm U23 to which the sensation induction device 300 is attached, it is desirable that the vibration direction of the vibration unit 303 is set so that vibration is more easily transmitted to the arm U23. Thus, in the example illustrated in FIG. 6, as described above, the vibration unit 303 is supported by the case 301 so that the vibration direction of the vibration unit 303 substantially matches the circumferential direction of the arm U23 to which the case 301 is attached (that is, the direction along the side surface of the arm U23, in which the belt-shaped member extends). On the other hand, the direction in which the vibration unit 303 is vibrated is not necessarily limited to the example illustrated in FIG. 8 as long as it is possible to present vibration with desired vibration intensity to the arm U23 to which the sensation induction device 300 is attached. That is, the vibration unit 303 may be supported by the case 301 so that the vibration direction of the vibration unit 303 substantially matches the direction perpendicular to the circumferential direction, as long as it is possible to present vibration with desired vibration intensity to the arm U23 to which the case 301 is attached.

As the modification of the sound output system according to the embodiment of the present disclosure, with reference to FIGS. 7 and 8, the description has been made above of the example of the case where the configuration related to output of sound and the configuration related to presentation of vibration are provided in different devices.

### 5. CONCLUSION

As described above, in a sound output system according to the embodiment of the present disclosure, a sensation induction device includes a vibration unit that has a long shape and vibrates in the long direction, and a support unit that supports the vibration unit in the vicinity of a portion where at least a part of a predetermined portion of a user contacts in a use state. In addition, vibration of the vibration unit is controlled on the basis of a part of frequency components included in sound to be output so that the vibration is associated with output of sound from a predetermined sound output unit. For example, vibration of the vibration unit may be controlled on the basis of a low frequency component of the sound to be output. As a more specific example, vibration of the vibration unit may be controlled on the basis of a fundamental wave of the frequency components included in the sound to be output.

With the configuration as described above, the sound output system according to the embodiment of the present disclosure can supplement, for example, even in a situation where a sound output device with limited sound reproduction performance is applied, a frequency component that is difficult to reproduce sound by the sound output device with vibration of the vibration unit. That is, with the sound output system according to the embodiment of the present disclosure, it is possible to present sound to a user in a more suitable manner even in a situation where a sound output device with limited performance to output a part of frequency components (for example, low frequency components) is applied.

The preferred embodiments of the present disclosure have been described above in detail with reference to the accompanying drawings, but the technical scope of the present disclosure is not limited to such examples. It is obvious that a person having ordinary knowledge in the technical field of the present disclosure can come up with various alterations or modifications within the scope of the technical idea described in the claims, and needless to say, it is understood that the alterations and the modifications also belong to the technical scope of the present disclosure.

In addition, the effects described in the present specification are merely illustrative or exemplary, and are not limitative. That is, the technology according to the present disclosure may exhibit other effects that are obvious to those skilled in the art from the description of the present specification, in addition to or in place of the effects described above.

Note that the following configurations also belong to the technical scope of the present disclosure.

(1) A sensation induction device comprising:

a vibration unit that has a long shape and vibrates in a long direction; and

a support unit that supports the vibration unit in a vicinity of a portion where at least a part of a predetermined portion of a user contacts in a state where the user listens to sound,

wherein vibration of the vibration unit is controlled on the basis of a part of frequency components included in sound to be output such that the vibration is associated with output of sound from a predetermined sound output unit.

(2) The sensation induction device according to (1), wherein vibration of the vibration unit is controlled on the basis of a low frequency component of the sound to be output.
(3) The sensation induction device according to (2), wherein vibration of the vibration unit is controlled on the basis of a fundamental wave of the frequency components included in the sound to be output.
(4) The sensation induction device according to any one of (1) to (3), further comprising the sound output unit,

wherein the support unit supports the sound output unit.

(5) The sensation induction device according to (4), wherein

the sound output unit outputs sound by vibrating a diaphragm, and

the support unit supports the vibration unit and the sound output unit such that a vibration direction of the vibration unit and a vibration direction of the diaphragm of the sound output unit are substantially perpendicular to each other, or are twisted from each other.

(6) The sensation induction device according to (5), wherein

the support unit

is configured as a plate-shaped case,

supports the sound output unit such that the vibration direction of the diaphragm of the sound output unit substantially matches a thickness direction, and

supports the vibration unit such that the vibration direction of the vibration unit is substantially perpendicular to the thickness direction.

(7) The sensation induction device according to any one of (4) to (6), wherein the support unit supports the vibration unit and the sound output unit such that the vibration unit and the sound output unit are separated from each other.
(8) The sensation induction device according to (7), wherein

the support unit

is configured as a case having a long shape, and

supports the vibration unit and the sound output unit such that the vibration unit and the sound output unit are separated from each other in a long direction of the case.

(9) The sensation induction device according to (8), wherein the case supports the vibration unit such that the long direction of the case and a vibration direction of the vibration unit are substantially perpendicular to each other.
(10) The sensation induction device according to any one of (4) to (9), wherein the support unit supports the vibration unit such that the vibration unit is positioned in a vicinity of a portion gripped by a hand of a user in a state where the user listens to sound output from the sound output unit.
(11) The sensation induction device according to any one of (4) to (10), wherein the support unit supports the sound output unit such that the sound output unit is positioned in a vicinity of an ear of a user in a state where the user listens to sound output from the sound output unit.
(12) The sensation induction device according to any one of (1) to (3), which is a device different from a device including the sound output unit.
(13) The sensation induction device according to (12), wherein, in a state where at least a part of the support unit is formed in a belt shape and is wound around a predetermined portion of a user, the support unit supports the vibration unit such that the vibration unit is positioned in a vicinity of a position that contacts a part of the portion.
(14) The sensation induction device according to (13), wherein the support unit supports the vibration unit such that a vibration direction of the vibration unit substantially matches a long direction of the belt-shaped portion.
(15) A sound output system comprising:

a sound output unit that outputs sound;

a vibration unit that has a long shape and vibrates in a long direction; and

a control unit that controls vibration of the vibration unit,

wherein the vibration unit is supported in a vicinity of a portion where at least a part of a predetermined portion of a user contacts in a state where the user listens to sound, and

the control unit controls vibration of the vibration unit on the basis of a part of frequency components included in sound to be output such that the vibration is associated with output of sound from the sound output unit.

### REFERENCE SIGNS LIST

1 SOUND OUTPUT SYSTEM
100 TERMINAL DEVICE
101 CASE
103 SOUND OUTPUT UNIT
105 VIBRATION UNIT
111 SOUND DECODER
113 FIRST OUTPUT UNIT
115 SECOND OUTPUT UNIT
117 SOUND PROCESSING UNIT
119 D/A CONVERTER
121 HAPTIC EFFECT CONVERSION PROCESSING UNIT
123 D/A CONVERTER
125 DYNAMIC RANGE ADJUSTMENT PROCESSING UNIT
127 FREQUENCY CORRECTION PROCESSING UNIT
129 DELAY PROCESSING UNIT
131 FREQUENCY ANALYSIS PROCESSING UNIT
133 WAVE HEIGHT CONVERSION PROCESSING UNIT
135 DELAY PROCESSING UNIT

1. A sensation induction device comprising:
a vibration unit that has a long shape and vibrates in a long direction; and
a support unit that supports the vibration unit in a vicinity of a portion where at least a part of a predetermined portion of a user contacts in a state where the user listens to sound,
wherein vibration of the vibration unit is controlled on the basis of a part of frequency components included in sound to be output such that the vibration is associated with output of sound from a predetermined sound output unit.

2. The sensation induction device according to claim 1, wherein vibration of the vibration unit is controlled on the basis of a low frequency component of the sound to be output.

3. The sensation induction device according to claim 2, wherein vibration of the vibration unit is controlled on the basis of a fundamental wave of the frequency components included in the sound to be output.

4. The sensation induction device according to claim 1, further comprising the sound output unit,
wherein the support unit supports the sound output unit.

5. The sensation induction device according to claim 4, wherein
the sound output unit outputs sound by vibrating a diaphragm, and
the support unit supports the vibration unit and the sound output unit such that a vibration direction of the vibration unit and a vibration direction of the diaphragm of the sound output unit are substantially perpendicular to each other, or are twisted from each other.

6. The sensation induction device according to claim 5, wherein
the support unit
is configured as a plate-shaped case,
supports the sound output unit such that the vibration direction of the diaphragm of the sound output unit substantially matches a thickness direction, and
supports the vibration unit such that the vibration direction of the vibration unit is substantially perpendicular to the thickness direction.

7. The sensation induction device according to claim 4, wherein the support unit supports the vibration unit and the sound output unit such that the vibration unit and the sound output unit are separated from each other.

8. The sensation induction device according to claim 7, wherein
the support unit
is configured as a case having a long shape, and
supports the vibration unit and the sound output unit such that the vibration unit and the sound output unit are separated from each other in a long direction of the case.

9. The sensation induction device according to claim 8, wherein the case supports the vibration unit such that the long direction of the case and a vibration direction of the vibration unit are substantially perpendicular to each other.

10. The sensation induction device according to claim 4, wherein the support unit supports the vibration unit such that the vibration unit is positioned in a vicinity of a portion gripped by a hand of a user in a state where the user listens to sound output from the sound output unit.

11. The sensation induction device according to claim 4, wherein the support unit supports the sound output unit such that the sound output unit is positioned in a vicinity of an ear of a user in a state where the user listens to sound output from the sound output unit.

12. The sensation induction device according to claim 1, which is a device different from a device including the sound output unit.

13. The sensation induction device according to claim 12, wherein, in a state where at least a part of the support unit is formed in a belt shape and is wound around a predetermined portion of a user, the support unit supports the vibration unit such that the vibration unit is positioned in a vicinity of a position that contacts a part of the portion.

14. The sensation induction device according to claim 13, wherein the support unit supports the vibration unit such that a vibration direction of the vibration unit substantially matches a long direction of the belt-shaped portion.

15. A sound output system comprising:
a sound output unit that outputs sound;
a vibration unit that has a long shape and vibrates in a long direction; and
a control unit that controls vibration of the vibration unit,
wherein the vibration unit is supported in a vicinity of a portion where at least a part of a predetermined portion of a user contacts in a state where the user listens to sound, and
the control unit controls vibration of the vibration unit on the basis of a part of frequency components included in sound to be output such that the vibration is associated with output of sound from the sound output unit.
